(19) United States
(12) Patent Application Publication
(10) Pub. No.: US 2024/0324271 A1
(43) Pub. Date: Sep. 26, 2024

(54) INK COMPOSITION, LIGHT EMITTING DEVICE MADE OF THE INK COMPOSITION, AND MANUFACTURING METHOD OF THE LIGHT EMITTING DEVICE

(71) Applicant: Samsung Display Co., LTD., Yongin-si (KR)

(72) Inventors: Yun Ku JUNG, Yongin-si (KR); YUNHYUK KO, Yongin-si (KR); WON-JUN PARK, Yongin-si (KR); CHUL SOON PARK, Yongin-si (KR); JONGWOO SHIN, Yongin-si (KR); Jungho JO, Yongin-si (KR)

(73) Assignee: Samsung Display Co., LTD., Yongin-si (KR)

(21) Appl. No.: 18/437,361

(22) Filed: Feb. 9, 2024

(30) Foreign Application Priority Data
Mar. 20, 2023 (KR) 10-2023-0036026

(51) Int. Cl. H10K 50/16; C09D 11/52; H10K 50/11; H10K 71/15

(52) U.S. Cl. CPC H10K 50/166; C09D 11/52; H10K 50/11; H10K 71/15

(57) ABSTRACT

An ink composition includes a first solvent, a second solvent, a first electron transport material and a second electron transport material. The first electron transport material includes a metal oxide, and a ligand disposed on a surface of the metal oxide. The second electron transport material includes a metal oxide, and a ligand positioned on a surface of the metal oxide. The ligand of the first electron transport material and the ligand of the second electron transport material are different from each other. A difference in a length of the ligand of the first electron transport material and a length of the ligand of the second electron transport material is three or more atoms.

### CROSS-REFERENCE TO RELATED APPLICATION(S)

This application claims priority to and the benefits of Korean Patent Application No. 10-2023-0036026 under 35 U.S.C. § 119, filed in the Korean Intellectual Property Office on Mar. 20, 2023, the entire contents of which are incorporated herein by reference.

### BACKGROUND

### 1. Technical Field

The disclosure relates to an ink composition, a light emitting device made of the ink composition, and a manufacturing method for the light emitting device.

### 2. Description of the Related Art

A light emitting device includes an anode, a cathode, and an emission layer formed between the anode and the cathode, and when holes from the anode and electrons from the cathode combine in the emission layer, the resulting excitons fall from the excited state to the ground state, generating light.

Such light emitting devices can be driven by low voltage, can be lightweight and thin, and have excellent characteristics such as viewing angle, contrast, and response speed, so their application range is expanding to many devices ranging from, e.g., portable mobile devices to televisions.

### SUMMARY

Embodiments relate to an ink composition, a light emitting device made of an ink composition, and a method for manufacturing a light emitting device, and to provide a method of manufacturing multiple layers of electron transport layers by a single process using one ink composition.

An ink composition according to an embodiment may include a first solvent, a second solvent, a first electron transport material, and a second electron transport material. The first electron transport material may include a metal oxide, and a ligand disposed on a surface of the metal oxide. The second electron transport material may include a metal oxide, and a ligand disposed on a surface of the metal oxide. The ligand of the first electron transport material and the ligand of the second electron transport material may be different from each other. A difference in a length of the ligand of the first electron transport material and a length of the ligand of the second electron transport material may be three or more atoms.

A ligand of the first electron transport material may have a length of two atoms or less.

A ligand of the first electron transport material may be acetic acid.

A ligand of the second electron transport material may have a length of five atoms or more.

A ligand of the second electron transport material may be (2-methoxyethoxy) ethanethiol.

The first solvent and the second solvent may have different boiling points, vapor pressures, and surface tensions.

A difference between a boiling point of the first solvent and a boiling point of the second solvent may be in a range of about 30° C. to about 50° C.

The first solvent may include at least one of tripropylene glycol monobutyl ether and triethylene glycol mono(2-ethylhexyl) ether.

The second solvent may include at least one of diethylene glycol t-butyl ether and tetraethylene glycol monomethyl ether.

A manufacturing method of forming an display device according to an embodiment may include applying an ink composition including a first solvent, a second solvent, a first electron transport material, and a second electron transport material to a first electrode disposed on a substrate, heating the ink composition to evaporate the first solvent and form the first electron transport layer including the first electron transport material, and heating the ink composition to evaporate the second solvent and form a second electron transport layer including the second electron transport material. The first electron transport material of the ink composition may include a metal oxide, and a ligand disposed on a surface of the metal oxide. The second electron transport material of the ink composition may include a metal oxide, and a ligand disposed on a surface of the metal oxide. The ligand of the first electron transport material and the ligand of the second electron transport material may be different from each other. A difference in a length of the ligand of the first electron transport material and a length of the ligand of the second electron transport material may be three or more atoms.

The method may further include, in the heating of the ink composition to evaporate the first solvent and the heating of the ink composition to evaporate the second solvent, forming a mixed region disposed between the first electron transport layer and the second electron transport layer and including both the first electron transport material and the second electron transport material.

A concentration of the first electron transport material of the first electron transport layer may be highest at a bottom of the first electron transport layer and decrease approaching an interface of the second electron transport layer.

A concentration of the second electron transport material of the second electron transport layer may be lowest at an interface with the first electron transport layer and may increase approaching a top of the second electron transport layer.

A viscosity of the ink composition may be in a range of about 5 cp to about 15 cp, a surface tension of the ink composition may be in a range of about 25 dyne/cm to about 40 dyne/cm, and a vapor pressure of the ink composition may be in a range of about 10-2 mmHg at about 25° C.

A display device according to an embodiment may include a first electrode disposed on a substrate and electrically connected to a transistor, an electron transport layer disposed on the first electrode, an emission layer disposed on the electron transport layer, and a second electrode disposed on the emission layer. The electron transport layer may include a first electron transport layer including a first electron transport material, a second electron transport layer including a second electron transport material, and a mixing layer disposed between the first electron transport layer and the second electron transport layer and including the first electron transport material and the second electron transport material.

The first electron transport material may include metal oxide, and a ligand disposed on a surface of the metal oxide, and the second electron transport material may include metal oxide, and a ligand positioned on a surface of the metal oxide. The ligand of the first electron transport material and the ligand of the second electron transport material may be different from each other.

A concentration of the first electron transport material of the first electron transport layer may be highest at a bottom of the first electron transport layer and decrease approaching an interface of the second electron transport layer.

A display device according to another embodiment may include a first electrode disposed on a substrate and electrically connected to a transistor, an electron transport layer disposed on the first electrode, an emission layer disposed on the second electron transport layer, and a second electrode disposed on the emission layer. The electron transport layer may include a first electron transport layer including a first electron transport material, and a second electron transport layer including a second electron transport material. The first electron transport material may include metal oxide, and a first ligand disposed on a surface of the metal oxide. The second electron transport material may include metal oxide, and a second ligand positioned on a surface of the metal oxide. The first ligand and the second ligand may be different from each other.

The display device may further include a mixing layer disposed between the first electron transport layer and the second electron transport layer and including the first electron transport material and the second electron transport material.

A thickness of the first electron transport layer may be greater than a thickness of the second electron transport layer.

According to embodiments, a method for manufacturing a multi-layer electron transport layer in a single process using one ink composition and a light emitting device manufactured by the method are provided.

### BRIEF DESCRIPTION OF THE DRAWINGS

FIGS. 1, 2, 3, and 4 are schematic cross-sectional views showing a manufacturing process of a light emitting device according to an embodiment.

FIG. 5 is a schematic cross-sectional view of a light emitting device according to an embodiment.

FIGS. 6, 7, 8, and 9 are schematic illustrations of electron transport layers according to Experimental Examples 1 to 4.

FIG. 10 is a schematic cross-sectional view of a display device including a light emitting element according to an embodiment.

### DETAILED DESCRIPTION OF THE EMBODIMENTS

Hereinafter, with reference to the accompanying drawings, various embodiments of the disclosure will be described in detail so that a person of ordinary skill in the art may readily practice the disclosure. The disclosure may be implemented in many different forms and is not limited to the embodiments described herein.

In order to clearly illustrate the disclosure, parts not pertinent to the description have been omitted, and identical or similar constituent elements are designated by the same reference numerals throughout the specification.

Furthermore, the size and thickness of each configuration shown in the drawings may be arbitrary for purposes of illustration and the disclosure is not necessarily limited to those shown.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Also, when it is said that parts such as layers, films, regions, plates, etc. are “above” or “on” other parts, this includes not only the case where they are “directly on” the other parts but also the case where there are other parts in between.

In contrast, when an element is referred to as being “directly on” another element, there may be no intervening elements present.

In addition, being “above” or “on” a reference part means being positioned (disposed) above or below the reference part, and does not necessarily mean being positioned “above” or “on” in the opposite direction of gravity.

In addition, throughout the specification, when a part “comprises,” “has,” or “includes” a certain component, it means that it may further include other components rather than excluding other components unless specifically stated to the contrary.

Also, throughout the specification, references to “in plan view” mean when the subject matter is viewed from above, and references to “cross-section view” mean when the subject matter is viewed from the side in a vertically cut section.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, an ink composition according to an embodiment, a method for manufacturing a light emitting device using the ink composition, and a light emitting device manufactured by the method will be described in detail with reference to the drawings.

An ink composition according to an embodiment may include a first solvent, a second solvent, a first electron transport material, and a second electron transport material.

The first electron transport material may be at least one metal oxide of ZnO, TiO₂, WO₃, SnO₂, and ZnO doped with at least one Mg, Y, Li, Ga, and Al.

Further, the second electron transport material may be at least one metal oxide of ZnO, TiO₂, WO₃, SnO₂, and ZnO doped with at least one of Mg, Y, Li, Ga, and Al.

The first electron transport material and the second electron transport material may include a ligand positioned on the surface of the metal oxide.

In this case, the ligands of the first electron transport material and the second electron transport material may be different.

For example, the ligand of the first electron transport material may be at least one of the structures having a tail length of two atoms or less.

For example, the ligand of the first electron transport material may be acetic acid.

Further, the ligand of the second electron transport material may be at least one of the structures having a tail length of five atoms or more.

For example, the ligand of the second electron transport material may be 2-(2-methoxyethoxy) ethanethiol.

The ligand length difference between the first electron transport material and the second electron transport material may be three or more atoms.

Since the ligand length and structure of the first electron transport material and the second electron transport material are different, the dispersibility of the first electron transport material and the second electron transport material may be different, thereby forming a multilayer electron transport layer with one ink composition.

The first electron transport material may be well dispersed in the first solvent and poorly dispersed in the second solvent.

The second electron transport material may be poorly dispersed in the first solvent and well dispersed in the second solvent.

The first solvent and the second solvent can be mixed well without layer separation.

The first solvent and the second solvent may have different boiling points, vapor pressures, and surface tensions.

The first solvent and the second solvent may have different Hassen solubility parameter values.

Specifically, the boiling point of the first solvent may be in a range of about 200 ° C. to about 250° C.

The vapor pressure of the first solvent may be in a range of about 5×10⁻² mm Hg to about 5×10⁻³ mm Hg.

The surface tension of the first solvent may be in a range of about 25 cp to about 30 cp.

The boiling point of the second solvent may be in a range of about 250° C. to about 300° C.

The vapor pressure of the second solvent may be in a range of about 1×10⁻² mm Hg to about 1×10⁻³ mm Hg.

The surface tension of the second solvent may be in a range of about 25 cp to about 30 cp.

The boiling point difference between the first solvent and the second solvent may be in a range of about 30 ° C. to about 50° C.

In case that the boiling point difference is less than about 20 ° C. (e.g., less than about 30° C.), the layer separation of the first electron transport material and the second electron transport material may not be well achieved, and in case that the boiling point difference is about 50 ° C. or more, there may be a problem in the uniformity of thin film formation.

For example, the first solvent may be at least one of tripropylene glycol monobutyl ether and triethylene glycol mono(2-ethylhexyl) ether.

The second solvent may be at least one of Diethylene glycol t-butyl ether and tetraethylene glycol monomethyl ether.

According to an embodiment, the ink composition may further comprise a third solvent.

The boiling point of the third solvent may be between the boiling point of the first solvent and the boiling point of the second solvent.

The vapor pressure of the third solvent may be between vapor pressure of the first solvent and the vapor pressure of the second solvent.

Specifically, the boiling point of the third solvent may be in a range of about 230° C. to about 260° C., and the vapor pressure may be in a range of about 3×10⁻² mm Hg to about 3×10⁻³ mm Hg.

For example, the third solvent may be at least one of trialkylene glycol isopropyl ether.

The viscosity of the ink composition according to an embodiment may be in a range of 5 cp to about 15 cp.

If the viscosity is less than about 3 cp or greater than about 15 cp, there may be ink discharge and thin film uniformity problems.

The surface tension of the ink composition according to an embodiment may be in a range of about 25 dyne/cm to about 40 dyne/cm.

If the surface tension is less than about 25 dyne/cm or greater than about 40 dyne/cm, there may be a problem with the discharge and thin film uniformity of the ink.

The vapor pressure of the ink composition according to an embodiment may be about 10⁻² mm Hg or less at room temperature (about 25° C.).

In case that the vapor pressure exceeds about 10⁻² mmHg, there may be a problem that staining occurs due to natural drying of the ink of the initially discharged pixels during the inkjet process.

The ink composition according to an embodiment may include a first solvent and a second solvent having different boiling points, a first electron transport material having different ligands lengths, and a second electron transport material.

The first electron transport material and the second electron transport material may have different dispersibility to the first solvent and the second solvent.

Thus, by a single process using one ink composition, multiple layers of electron transport layers can be formed.

A method for manufacturing a light emitting device using an ink composition according to an embodiment will be described below.

The ink composition according to an embodiment may be a composition for forming an electron transport layer of a light emitting device, which will be described below centered on the formation of an electron transport layer.

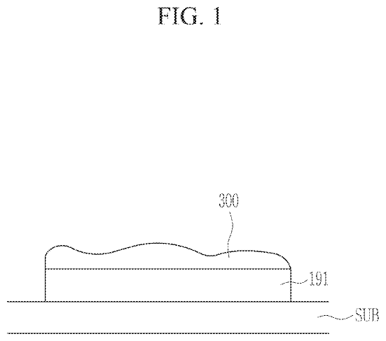

FIG. 1 to FIG. 4 are schematic cross-sectional views illustrating a manufacturing process of a light emitting device according to an embodiment.

Referring to FIG. 1, the ink composition 300 according to an embodiment may be applied on the first electrode 191 positioned on the substrate SUB.

Although not shown in FIG. 1, the first electrode 191 may be connected to a transistor to receive a pixel voltage.

In an embodiment, an electron transport layer may be positioned between the first electrode 191 and the emission layer EML for receiving a pixel voltage, and a hole transport layer may be positioned between the second electrode 270 and the emission layer EML for receiving a common voltage.

In the case of such a structure, by forming a hole transport layer after the formation of the emission layer, there may be an advantage that the selection of hole transport layer forming material may be free.

However, this is only an example, and the manufacturing method according to an embodiment is a hole transport layer HTL positioned between the first electrode 191 and the emission layer EML for receiving a pixel voltage, and an electron transport layer ETL1 may be positioned between the second electrode 270 and the emission layer EML.

The ink composition 300 applied in FIG. 1 may be the ink composition 300 as described above, and a detailed description of the same component is omitted.

For example, the ink composition 300 according to an embodiment may include a first solvent and a second solvent having different boiling points, a first electron transport material and a second electron transport material having different ligands lengths, and the dispersibility of the second solvent may be different.

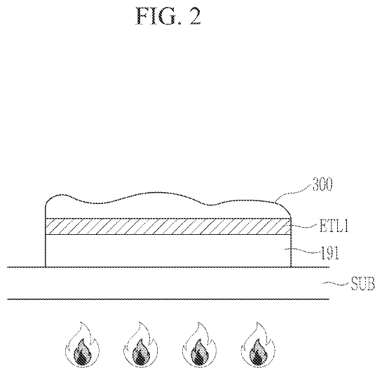

Referring to FIG. 2, the applied ink composition 300 may be heated.

The first solvent having a low boiling point and a high vapor pressure may be evaporated by heating.

At this time, the first electron transport material dispersed in the first solvent may be precipitated to form a first electron transport layer ETL1.

The first electron transport material was well dispersed in the first solvent and not well dispersed in the second solvent, and the first electron transport layer ETL1 may be formed upon evaporation of the first solvent.

In this case, the thickness of the first electron transport layer ETL1 may be in a range of about 150 nm to about 250 nm.

In case that the thickness is less than about 150 nm, in order to form an appropriate thickness of the entire electron transport layer ETL1, there may be a problem that the electron mobility decreases as the thickness of the second electron transport layer ETL2 with low electron mobility increases.

In case that the thickness of the first electron transport layer ELT1 exceeds about 250 nm, the thickness of the second electron transport layer ETL2 may be lowered, making it difficult to control thin film formation and resulting in poor thin film uniformity.

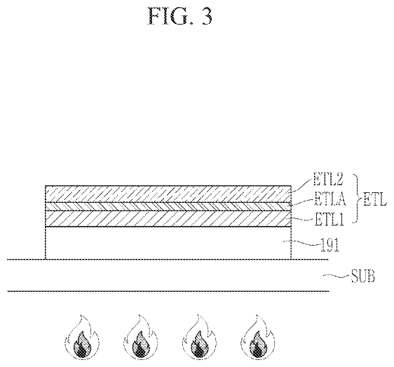

Referring to FIG. 3, the ink composition 300 may be positioned on the first electron transport layer ETL1 and may heat the first electron transport layer ETL1.

The second solvent may be evaporated by heating.

At this time, the second electron transport material dispersed in the second solvent may be precipitated to form a second electron transport layer ETL2.

The second electron transport layer ETL2 may be formed on the first electron transport layer ETL1.

In this case, the thickness of the second electron transport layer ETL2 may be in a range of about 20 nm to about 40 nm.

In case that the thickness of the second electron transport layer ETL2 is less than about 20 nm, it may be difficult to form an independent thin film due to the low thickness, and there may be a problem that the surface roughness of the thin film deteriorates, and in case that the thickness is greater than about 40 nm, there may be a problem that electron mobility decreases.

The thickness of the second electron transport layer ETL2 may be thinner than the thickness of the first electron transport layer ETL1 in an embodiment.

However, as shown in FIG. 3, a mixing region ETLA may be positioned between the first electron transport layer ETL1 and the second electron transport layer ETL2.

For example, the formation of the electron transport layer ETL1 according to an embodiment may not form a first electron transport layer ETL1 and a second electron transport layer ETL2 with each process, but phase separation using one ink composition to form a first electron transport layer ETL1 and a second electron transport layer ETL2.

Thus, a mixed layer of the first electron transport material and the second electron transport material may be formed during the phase separation process, and between the first electron transport layer ETL1 and the second electron transport layer ELT2, a mixing region ETLA may be disposed comprising both the first electron transport material and the second electron transport material.

A gradual concentration gradient of the first electron transport material can be made within the first electron transport layer ETL1.

The concentration of the first electron transport material may be highest at a bottom of the first electron transport layer ETL1 and may decrease as approaching an interface of the second electron transport layer ETL2.

Similarly, the concentration of the second electron transport material may be lowest at an interface with the lower part of the second electron transport layer ETL2, that is, the first electron transport layer ETL1, and may increase towards a top of the second electron transport layer ETL2.

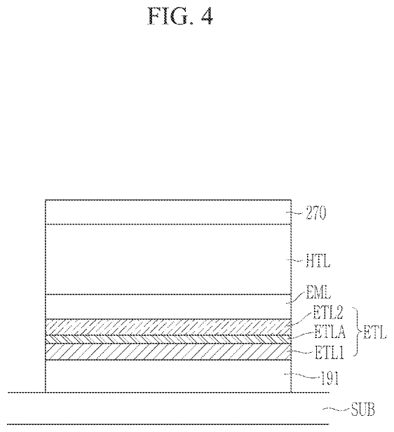

Referring to FIG. 4, an emission layer EML, a hole transport layer HTL, and a second electrode 270 may be formed in turn on the electron transport layer ETL1 to form a light emitting device.

At this time, the emission layer EML may include quantum dots.

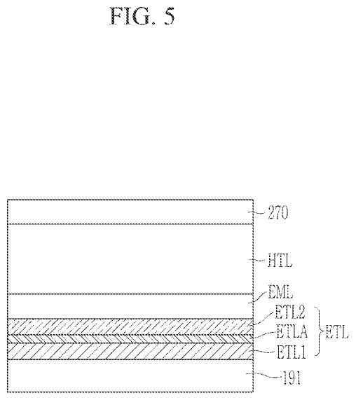

FIG. 5 is a schematic cross-section of a light emitting device according to an embodiment.

Referring to FIG. 5, a light emitting device including an electron transport layer ETL1 according to an embodiment will be described in detail.

The first electrode 191 and the second electrode 270 may be conductive oxides such as indium tin oxide (ITO), indium zinc oxide (IZO), zinc tin oxide (ZTO), copper indium oxide (CIO), copper zinc oxide (CZO), gallium zinc oxide (GZO), aluminum zinc oxide (AZO), tin oxide (SnO2), zinc oxide (ZnO), calcium (Ca), ytterbium (Yb), aluminum (Al), silver (Ag), magnesium (Mg), samarium (Sm), titanium (Ti), gold (Au), alloys thereof, graphene, carbon nanotubes, and/or conductive polymers such as PEDOT: PSS.

However, the first electrode 191 and the second electrode 270 are not limited thereto. The first electrode 191 and the second electrode 270 may be formed in a stacked structure of two or more layers.

In an embodiment, the first electrode 191 may be a reflecting electrode, and the second electrode 270 may be a semi-transflective electrode.

The light generated in the emission layer EML may be reflected from the first electrode 191, which is a reflecting electrode, and may be resonated and amplified between the second electrode 270 and the first electrode 191, which is a semi-transflective electrode.

The resonant light may be reflected from the first electrode 191 and emitted to the upper surface of the second electrode 270.

In other embodiments, the second electrode 270 may be a reflecting electrode, and the first electrode 191 may be a semi-transflective electrode.

The light generated in the emission layer EML may be reflected from the second electrode 270, which is a reflecting electrode, and may be resonated and amplified between the first electrode 191 and the second electrode 270, which are semi-transflective electrodes.

The resonant light may be reflected from the second electrode 270 and emitted to the upper surface of the first electrode 191.

The hole transport layer HTL can include at least one of m-MTDATA, TDATA, 2-TNATA, NPB(NPD), β-NPB, TPD, Spiro-TPD, Spiro-NPB, methylated-NPB, TAPC, HMTPD, TCTA(4,4′, 4″-tris(N-carbazolyl)triphenylamine (4,4′, 4″-tris(N-carbazolyl)triphenylamine)), Pani/DBSA (Polyaniline/Dodecylbenzenesulfonic acid (Polyaniline/Dodecylbenzenesulfonic acid)), PEDOT/PSS(Poly(3,4-ethylenedioxythiophene)/Poly(4-styrenesulfonate) (Poly(3,4-ethylenedioxythiophenc)/Poly(4-styrenesulfonate))), Pani/CSA (Polyaniline/Camphor sulfonic acid (Polyaniline/Camphor sulfonic acid)), PANI/PSS (Polyaniline/Poly(4-styrenesulfonate) (Polyaniline/Poly(4-styrenesulfonate))).

In other embodiments, the hole transport layer may include an alkali metal halide or an alkaline earth metal halide.

The emission layer EML may include an organic material or an inorganic material.

The emission layer may include quantum dots.

For example, the quantum dot may include at least one of Zn, Te, Se, Cd, In, and P.

The quantum dot may include a core comprising at least one of Zn, Te, Se, Cd, In, and P, and a shell positioned on a portion of the core and having a composition different from the core.

Specifically, quantum dots can be selected from group II-VI compounds, I-III-VI compounds, III-V compounds, IV-VI compounds, IV elements, group IV compounds, and combinations thereof.

The quantum dot may be a group of group II-VI compounds CdSe, CdTe, CdS, ZnS, ZnSe, ZnTe, ZnO, HgS, HgSe, HgTe, MgSe, MgS, and mixtures thereof. CdZnSTe, CdHgSeS, CdHgSeTe, CdHgSTe, HgZnSeS, HgZnSeTe, HgZnSTe and mixtures thereof can be selected from the group consisting of temple-like compounds.

The quantum dot may be selected from a trielement compound selected from the group consisting of I-III-VI compounds AgInS, CuInS, AgGaS, CuGaS and mixtures thereof, or from a quarrel compound such as AgInGaS and CuInGaS.

Group III-V compounds may be diatomic compounds selected from the group consisting of GaN, GaP, GaAs, GaSb, AlN, AIP, AlAs, AlSb, InN, InP, InAs, and mixtures thereof, GaNPs, GaNAs, GaNSb, GaPAs, GaPSb, AlNP, AlNAs, AlNSb, AlPAs, AlPSb, InGaP, InAlP, InNPs, InNAs, InNSb, InPAs, InPSb and mixtures thereof, and GaAlNP, GaAlNAs, GaAlNSb, GaAlPAs, GaAlPSb, GaInNPb, GaInPAb, GaInNPs, InAlNAb, InAlNAb, InAlPAs, InAlPAs, InAlPSb and mixtures thereof, meanwhile, group III-V compounds may further comprise group II metals (e.g., InZnP) and may be selected from these compounds.

Group IV-VI compounds may include diatomic compounds selected from the group consisting of SnS, SnSe, SnTe, PbS, PbSe, PbTe and mixtures thereof, SnSeS, SnSeTe, SnSTe, PbSeS, PbSeTe, PbSTe, SnPbS, SnPbSe, SnPbTe and mixtures thereof.

Group IV elements may be selected from the group consisting of Si, Ge and mixtures thereof, and group IV compounds may be diatomic compounds selected from the group consisting of SiC, SiGe and mixtures thereof.

The electron transport layer ETL1 may include a first electron transport layer ETL1 and a second electron transport layer ETL2.

An embodiment may include a mixed region ETLA positioned between the first electronic transport layer ETL1 and the second electronic transport layer ETL2.

The first electron transport layer ETL1 may include a first electron transport material.

The first electron transport material may be at least one metal oxide selected from the group consisting of ZnO, TiO₂, WO₃, SnO₂ and Mg, Y, Li, Ga, Al doped ZnO, TiO₂, WO₃, SnO₂.

The first electron transport material may include a ligand positioned on the metal oxide surface.

For example, the ligand of the first electron transport material may be acetic acid.

The thickness of the first electron transport layer ETL1 may be in a range of about 150 nm to about 250 nm.

In case that the thickness of the first electron transport layer ETL1 is less than about 150 nm, in order to form an appropriate thickness of the entire electron transport layer ETL1, the thickness of the second electron transport layer ETL2 with low electron mobility increases.

In case that the thickness of the first electron transport layer ELT1 exceeds about 250 nm, the thickness of the second electron transport layer ETL2 may be lowered, making it difficult to control thin film formation and resulting in poor thin film uniformity.

The concentration of the first electron transport material in the first electron transport layer ETL1 may be highest at the bottom of the first electron transport layer ETL1 and may decrease approaching the interface of the second electron transport layer ETL2.

The second electron transport layer ETL2 may include a second electron transport material.

The second electron transport material may be at least one metal oxide selected from the group consisting of ZnO, TiO₂, WO₃, SnO₂ and Mg, Y, Li, Ga, Al doped ZnO, TiO₂, WO₃, SnO₂.

The second electron transport material may include a ligand positioned on the metal oxide surface.

For example, the ligand of the second electron transport material may be 2-(2-methoxyethoxy) ethanethiol.

The ligand lengths of the first electron transport material and the second electron transport material may be different, and the ligand length difference between the first electron transport material and the second electron transport material may be three or more atoms.

In this case, the thickness of the second electron transport layer ETL2 may be in a range of about 20 nm to about 40 nm.

In case that the thickness of the electron transport layer ETL2 is less than about 20 nm, independent thin film formation may be difficult due to low thickness and the surface roughness of the thin film may be worse, and in case that the thickness is greater than about 40 nm, electron mobility may be reduced.

The concentration of the second electron transport material may be lowest at the interface with the lower part of the second electron transport layer ETL2, that is, the first electron transport layer ETL1, and may increase towards the top of the second electron transport layer ETL2.

Thus, the light emitting device according to an embodiment may include a first electron transport layer comprising a first electron transport material and a second electron transport layer comprising a second electron transport material to improve the luminous efficiency.

Hereinafter, the effect of the light emitting device according to an embodiment will be described.

In this experimental example, ZnO may be used as the first electron transport material, and ZnO may include a ligand having two or fewer carbon numbers.

The second electron transport material may use ZnMgO, which may include a ligand with a carbon number of 5 or more, and the ligand including carbon and oxygen.

Specifically, the ligand included in ZnO may be acetic acid, and the ligand included in ZnMgO may be 2-(2-methoxyethoxy) ethanethiol.

Experimental Example 1 may be formed by mixing first electron transport material E1 and second electron transport material E2 to form one electron transport layer.

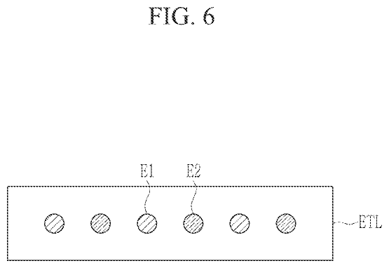

The electron transport layer ETL1 of Experimental Example 1 is shown in FIG. 6.

Experimental Example 2 may form the first electron transport layer ETL1 with the first electron transport material E1, and mix the first electron transport material E1 and the second transfer transport material E2 to form a second electron transport layer ETL2.

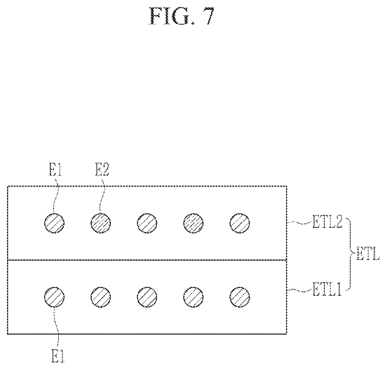

The electron transport layer ETL1 of Experimental Example 2 is shown in FIG. 7.

Experimental Example 3 may form the first electron transport layer ETL1 with the first electron transport material E1 and the second electron transport layer ETL2 with the second electron transport material E2.

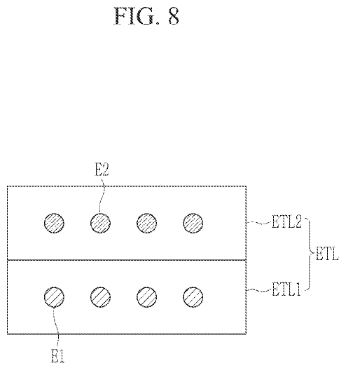

Experimental Example 3's electron transport layer ETL1 is shown in FIG. 8.

Experimental Example 4 may evaporate one ink including first electron transport material E1 and second electron transport material E2 by phase separation to form a first electron transport layer ETL1 including the first electron transport material E1 and a second electron transport material E2 comprising the first electron transport material according to an embodiment.

Experimental Example 4 may include a mixed region ETLA positioned between the first electron transport layer ELT1 and the second electron transport layer ETL2 and may include both the first electron transport material E1 and the second electron transport material E2.

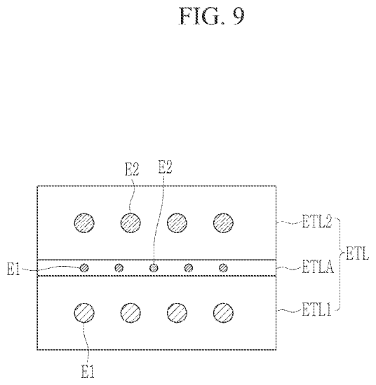

The electron transport layer of Experimental Example 4 is shown in FIG. 9.

In FIG. 6 to FIG. 9, for better comprehension and ease of description, the first electron transport material E1 and the second electron transport material E2 are shown in the form of particles, but embodiments are not limited thereto, the first electron transport material E1 or the second electron transport material E2 may be otherwise disposed.

Table 1 below measures the driving voltage and efficiency of a light emitting device including an electron transport layer according to an embodiment of the Experimental Examples 1 to 4, that is, FIG. 6 to FIG. 9.

Referring to Table 1, in experimental examples 3 and 4 including a first electron transport layer ETL1 including a first electron transport material E1 and a second electron transport layer ETL2 including a second electron transport material E2, the driving voltage may decrease and the efficiency may increase compared to experimental examples 1 and 2 in which the first electron transport material E1 and the second electron transport material E2 are mixed.

TABLE 1

| | driving voltage | efficiency |
|---|---|---|
| | (@ 5 mA/cm2) | (cd/A) |
| Experimental Example 1 | 9.2 V | 8.1 |
| Experimental Example 2 | 8.4 V | 10.2 |
| Experimental Example 3 | 7.3 V | 17.1 |
| Experimental Example 4 | 7.4 V | 16.5 |

Experimental Example 3 in which a first electron transport layer ETL1 may be formed with the first electron transport material E1 and a second electron transport layer ETL2 with the second electron transport material E2 is compared, and with a second electron transport layer ETL2 comprising a first electron transport material E1 and a second electron transport layer ETL12 including a second electron transport material E2 by phase separation using one ink according to an embodiment, it was confirmed that the embodiment had the characteristics of an equivalent level.

In an embodiment, it was confirmed that the manufacturing process can be simplified while having the same characteristics compared to the case in which the first electron transport layer and the second electron transport layer are formed by separate processes.

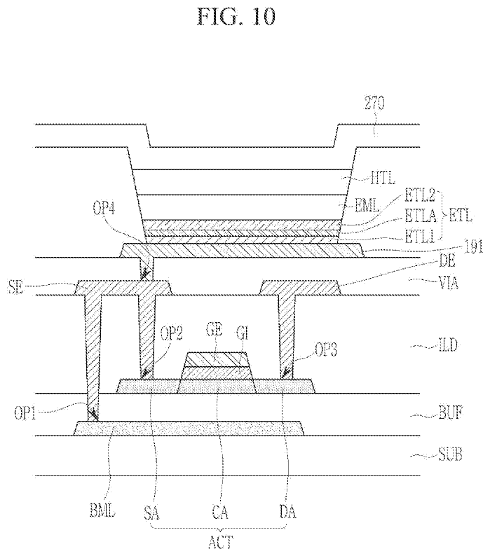

FIG. 10 is a schematic cross-section of a display device including a light emitting element according to an embodiment.

FIG. 10 illustrates a portion of a cross-section for better comprehension and ease of description, and the disclosure is not limited thereto.

Referring to FIG. 10, a substrate SUB may be positioned.

The substrate SUB may include polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and/or cellulose acetate propionate.

The substrate SUB may be a rigid substrate or a flexible substrate capable of bending, folding, rolling, and the like.

The substrate SUB may be single-layer or multi-layer.

The substrate SUB may be stacked by alternating at least one base layer including a sequentially laminated polymer resin and at least one inorganic layer.

A light barrier layer BML may be positioned on the substrate SUB.

The light barrier layer BML may include aluminum (Al), silver (Ag), magnesium (Mg), gold (Au), nickel (Ni), chromium (Cr), calcium (Ca), molybdenum (Mo), titanium (Ti), tungsten (W), copper (Cu), and/or metal oxides, and may be a single layer or a multi-layered structure including the same.

A buffer layer BUF may be positioned on top of the light barrier layer BML.

The buffer layer BUF may include silicon oxide (SiOx), silicon nitride (SiNx), silicon nitride (SiOxNy), and/or amorphous silicon (Si).

The buffer layer BUF may include a first aperture OP1 overlapping with the light barrier layer BML.

In the first opening OP1, the source electrode SE may be connected to the light barrier layer BML.

The semiconductor layer ACT may be positioned on the buffer layer BUF.

The semiconductor layer ACT may include polycrystalline silicon.

The semiconductor layer ACT may include a channel area CA overlapping the gate electrode GE and a source area SA and a drain area DA positioned on both the channel area.

A gate insulation film GI may be positioned on the semiconductor layer ACT.

The gate insulation film GI may include silicon oxide (SiOx), silicon nitride (SiNx), and/or silicon nitride (SiOxNy), and may be a single layer or a multi-layered structure including the same.

The gate insulating film GI may be positioned overlapping with the channel area CA of the semiconductor layer ACT.

A gate conductive layer including a gate electrode GE may be positioned on the gate insulating film GI.

The gate conductive layer may include molybdenum (Mo), aluminum (Al), copper (Cu), titanium (Ti) and/or metal oxides, and may be a single layer or a multi-layered structure comprising the same.

The gate electrode GE may be formed in the same process as the gate insulating film GI and have the same planar shape.

The gate electrode GE may overlap the surface of the semiconductor layer ACT and the substrate SUB in a vertical direction.

An interlayer insulating film ILD may be positioned on the semiconductor layer ACT and the gate electrode GE.

The interlayer insulating film ILD may include silicon oxide (SiOx), silicon nitride (SiNx), and/or silicon nitride (SiOxNy), and may be a single layer or a multi-layered structure comprising the same.

In case that the interlayer insulating film ILD is a multi-layered structure including silicon nitride and silicon oxide, the layer including the silicon nitride may be positioned closer to the substrate SUB than the layer including silicon oxide.

The interlayer insulating film ILD may include a first opening OP1 overlapping the light barrier layer BML, a second opening OP2 overlapping the source area SA of the semiconductor layer ACT, and a third opening OP3 overlapping the drain area DA.

A data conductive layer including a source electrode SE and a drain electrode DE may be positioned on the interlayer insulating film ILD.

The data conductive layer may include aluminum (Al), silver (Ag), magnesium (Mg), gold (Au), nickel (Ni), chromium (Cr), calcium (Ca), molybdenum (Mo), titanium (Ti), tungsten (W), and/or copper (Cu) and metal oxides, and may be a single layer or a multi-layered structure including the same.

The source electrode SE may contact the light barrier layer BML at the first opening OP1 and the source area SA of the semiconductor layer ACT at the second opening OP2.

The drain electrode DE may contact the drain area DA of the semiconductor layer ACT at the third opening OP3.

An insulation film VIA may be positioned on the data conductive layer.

The insulation film VIA may include general purpose polymers such as polymethylmethacrylate (PMMA) or polystyrene (PS), polymer derivatives having phenolic groups, acryl-based polymers, imide polymers, polyimides, siloxane polymers, and/or other organic insulating materials.

The insulation film VIA may include a fourth opening OP4 that overlaps the source electrode SE.

The first electrode 191 may be positioned on the insulating film VIA.

An electron transport layer ETL1, an emission layer EML, a hole transport layer HTL, and a second electrode 270 may be positioned on the first electrode 191.

The electron transport layer ETL1, the emission layer EML, the hole transport layer HTL, and the second electrode 270 on the first electrode 191 may constitute a light emitting device ETL, and a detailed description of the light emitting device is omitted as described above.

For example, a mixing region ETLA may be positioned between a first electron transport layer ELT1 including a first electron transport material, a second electron transport layer ETL2 including a second electron transport material. A mixing region ETLA may include both the first electron transport material E1 and the second electron transport material E2.

The specific description may be the same as described above.

Although embodiments of the disclosure have been described in detail above, the scope of rights of the disclosure is not limited thereto, and various modifications and modifications of a person of ordinary skill in the art using the basic concepts of the disclosure also fall within the scope of the disclosure.

What is claimed is:

1. An ink composition, comprising:
a first solvent;
a second solvent;
a first electron transport material; and
a second electron transport material, wherein
the first electron transport material comprises:
metal oxide; and
a ligand disposed on a surface of the metal oxide,
the second electron transport material comprises:
metal oxide; and
a ligand disposed on a surface of the metal oxide,
the ligand of the first electron transport material and the ligand of the second electron transport material are different from each other, and
a difference in a length of the ligand of the first electron transport material and a length of the ligand of the second electron transport material is three or more atoms.

2. The ink composition of claim 1, wherein the ligand of the first electron transport material has a length of two atoms or less.

3. The ink composition of claim 1, wherein the ligand of the first electron transport material is acetic acid.

4. The ink composition of claim 1, wherein the ligand of the second electron transport material has a length of five atoms or more.

5. The ink composition of claim 1, wherein the ligand of the second electron transport material is a 2-(2-methoxyethoxy) ethanethiol.

6. The ink composition of claim 1, wherein the first solvent and the second solvent have different boiling points, vapor pressures, and surface tensions.

7. The ink composition of claim 6, wherein a difference between a boiling point of the first solvent and a boiling point of the second solvent is in a range of about 30° C. to about 50° C.

8. The ink composition of claim 1, wherein the first solvent comprises at least one of tripropylene glycol monobutyl ether and triethylene glycol mono (2-ethylhexyl) ether.

9. The ink composition of claim 1, wherein the second solvent comprises an ink composition of at least one of diethylene glycol t-butyl ether and tetraethylene glycol monomethyl ether.

10. A manufacturing method of a display device, comprising:
applying an ink composition comprising a first solvent, a second solvent, a first electron transport material, and a second electron transport material to a first electrode disposed on a substrate;
heating the ink composition to evaporate the first solvent and form a first electron transport layer including the first electron transport material; and
heating the ink composition to evaporate the second solvent and form a second electron transport layer including the second electron transport material, wherein
the first electron transport material of the ink composition comprises metal oxide, and a ligand disposed on a surface of the metal oxide,
the second electron transport material of the ink composition comprises metal oxide, and a ligand disposed on a surface of the metal oxide,
the ligand of the first electron transport material and the ligand of the second electron transport material are different from each other, and
a difference in a length of the ligand of the first electron transport material and a length of the ligand of the second electron transport material is three or more atoms.

11. The manufacturing method of the display device of claim 10, further comprising:
in the heating of the ink composition to evaporate the first solvent and in the heating of the ink composition to evaporate the second solvent:
forming a mixing region disposed between the first electron transport layer and the second electron transport layer and including both the first electron transport material and the second electron transport material.

12. The manufacturing method of the display device of claim 10, wherein a concentration of the first electron transport material of the first electron transport layer is highest at a bottom of the first electron transport layer and decreases approaching an interface of the second electron transport layer.

13. The manufacturing method of the display device of claim 10, wherein a concentration of the second electron transport material of the second electron transport layer is lowest at an interface of the first electron transport layer and increases approaching a top of the second electron transport layer.

14. The manufacturing method of the display device of claim 10, wherein
a viscosity of the ink composition is in a range of about 5 cp to about 15 cp,
a surface tension of the ink composition is in a range of about 25 dyne/cm to about 40 dyne/cm, and
a vapor pressure of the ink composition is in a range of about 10-2 mmHg at about 25° C.

15. A display device, comprising:
a first electrode disposed on a substrate and electrically connected to a transistor;
an electron transport layer disposed on the first electrode;
an emission layer disposed on the electron transport layer; and
a second electrode disposed on the emission layer,
wherein the electron transport layer comprises:
a first electron transport layer comprising a first electron transport material;
a second electron transport layer comprising a second electron transport material; and
a mixing layer disposed between the first electron transport layer and the second electron transport layer and including the first electron transport material and the second electron transport material.

16. The display device of claim 15, wherein
the first electron transport material comprises metal oxide, and a ligand disposed on a surface of the metal oxide,
the second electron transport material comprises metal oxide, and a ligand disposed on a surface of the metal oxide, and
the ligand of the first electron transport material and the ligand of the second electron transport material are different each other.

17. The display device of claim 15, wherein a concentration of the first electron transport material of the first electron transport layer is highest at a bottom of the first electron transport layer and decreases approaching an interface of the second electron transport layer.

18. A display device, comprising:
a first electrode disposed on a substrate and electrically connected to a transistor;
an electron transport layer disposed on the first electrode;
an emission layer disposed on the electron transport layer; and
a second electrode disposed on the emission layer, wherein
the electron transport layer includes:
a first electron transport layer comprising a first electron transport material; and
a second electron transport layer comprising a second electron transport material,
the first electron transport material comprises metal oxide, and a first ligand disposed on a surface of the metal oxide,
the second electron transport material comprises metal oxide, and a second ligand disposed on a surface of the metal oxide, and
the first ligand and the second ligand are different each other.

19. The display device of claim 18, further comprising:
a mixing layer disposed between the first electron transport layer and the second electron transport layer and comprising the first electron transport material and the second electron transport material.

20. The display device of claim 18, wherein a thickness of the first electron transport layer is thicker than a thickness of the second electron transport layer.
